(19) United States
(12) Patent Application Publication
(10) Pub. No.: US 2014/0252349 A1
(43) Pub. Date: Sep. 11, 2014

(54) THIN FILM TRANSISTOR

(71) Applicant: PANASONIC CORPORATION, Osaka (JP)

(72) Inventor: Eiichi SATOH, Hyogo (JP)

(73) Assignee: PANASONIC CORPORATION, Osaka (JP)

(21) Appl. No.: 14/282,880

(22) Filed: May 20, 2014

Related U.S. Application Data
(63) Continuation of application No. PCT/JP2012/007517, filed on Nov. 22, 2012.

(30) Foreign Application Priority Data
Jan. 20, 2012 (JP) 2012-009866

(51) Int. Cl. H01L 29/786; H01L 29/66

(52) U.S. Cl. CPC H01L 29/78693; H01L 29/66969
USPC 257/43

(57) ABSTRACT

A thin film transistor includes a gate electrode formed on a substrate; a gate insulation film covering the gate electrode; a semiconductor layer formed on the gate insulation film; an etching stopper film formed on a channel forming portion of the semiconductor layer; and a source electrode and a drain electrode covering an edge portion of the semiconductor layer and a first edge portion of the etching stopper film. A second edge portion, not covered with the source electrode and drain electrode, of the etching stopper film is covered with a dummy pattern.

### TECHNICAL FIELD

The present disclosure relates to a TFT (Thin Film Transistor) used for LCD (Liquid Crystal Device) displays or OLED (Organic Light Emitting Device) displays.

### BACKGROUND

In recent years, OLED (Organic Light Emitting Device) displays using current-driven organic electro-luminescence device have drawn attention. Among these displays, an active-matrix driven OLED display employs a field effect transistor. TFT (Thin Film Transistor) is one of the field effect transistors, and has a semiconductor layer, which will become a channel forming region, disposed on a substrate of insulated surface.

TFTs, used in the active-matrix driven OLED displays, require at least a switching transistor controlling the timing of ON/OFF driving of OLED and a driving transistor controlling the amount of luminescence of OLED. These TFTs should have good transistor characteristics. Various researches are being conducted regarding such TFTs.

For example, the switching transistor is required to have less OFF-current and to have smaller dispersion between ON-current and OFF-current. The driving transistor is required to have larger ON-current and to have smaller dispersion in ON-current.

Conventionally, an amorphous silicon film, i.e. non-crystalline silicon film, is employed as a channel forming region of such TFTs, but there is disadvantage that ON current is low because of low mobility of non-crystalline silicon film. For this reason, crystallization of non-crystalline silicon film using heat-treatment by laser beam has been under research and development in recent years to obtain driving capability (ON current) of TFT.

When such crystallized silicon film is employed for TFTs, an ohmic contact layer is formed on the channel forming domain, and then the contact layer undergoes a process which may cause some damage to the channel forming domain. This damage degrades the characteristics of TFT.

One proposed approach is to form an insulated film in TFT for reducing the damage of channel forming region during the process of ohmic contact layer (Refer to patent literature JP 2007-305701 A1).

However, this conventional structure has a problem that the electric field may concentrate between the ohmic contact layer and the crystallized silicon film because the ohmic contact layer and the crystallized silicon film are in direct contact, which adversely increases the OFF current.

### SUMMARY

A thin film transistor of the present disclosure includes a gate electrode formed on a substrate; a gate insulation film covering the gate electrode; a semiconductor layer formed on the gate insulation film; an etching stopper film formed on a channel forming portion of the semiconductor layer; and a source electrode and a drain electrode covering an edge portion of the semiconductor layer and a first edge portion of the etching stopper film. A second edge portion, not covered with the source electrode and drain electrode, of the etching stopper film is covered with a dummy pattern.

The foregoing structure prevents an excessive increase in the manufacturing processes and provides TFTs of stabilized characteristics.

### BRIEF DESCRIPTION OF DRAWINGS

FIG. 1 is a perspective diagram of an EL display according to an exemplary embodiment.

FIG. 2 is a perspective diagram illustrating an example of a pixel bank of the EL display.

FIG. 3 is a circuit diagram illustrating a circuit structure of a pixel circuit in a TFT according to an exemplary embodiment.

FIG. 4 is a schematic plan view illustrating the TFT.

FIG. 5 is a sectional view cut along line 5-5 in FIG. 4.

FIG. 6 is a sectional view cut along line 6-6 in FIG. 4.

FIG. 7 is a schematic sectional view illustrating an advantage of the TFT in accordance with an exemplary embodiment.

### DETAILED DESCRIPTION

An embodiment of a TFT of the present disclosure will be described hereafter with reference to the accompanying drawings.

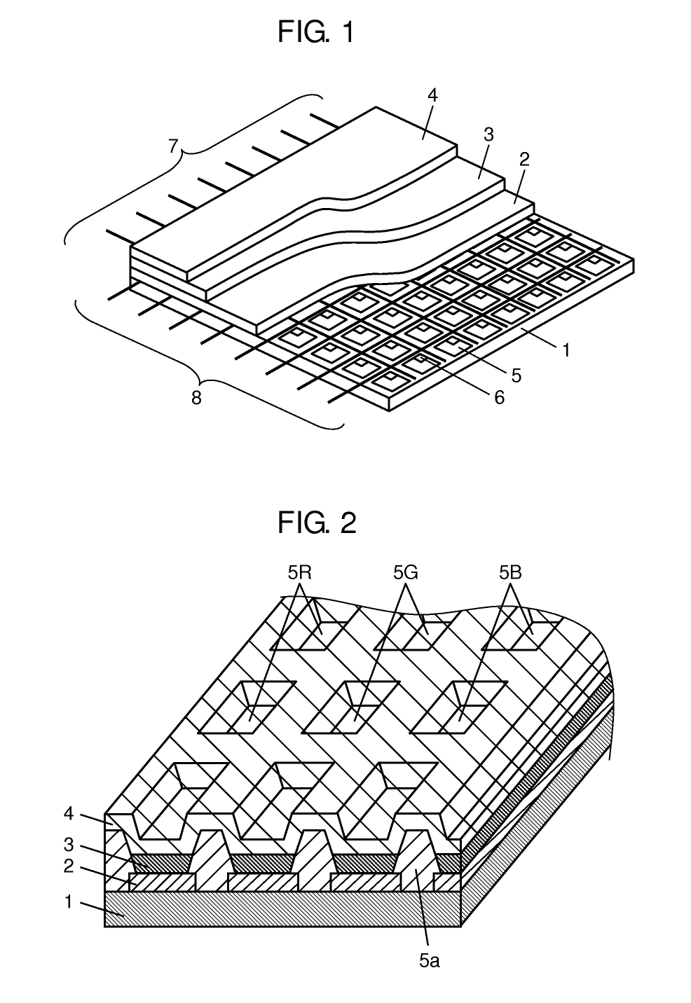

As illustrated in FIGS. 1 to 3, an EL (Electro Luminescence) display comprises TFT array unit 1, anode 2 (lower electrode), EL (Electro Luminescence) layer 3, cathode 4 (upper electrode) layered together in this order from the bottom. TFT array unit 1 includes multiple TFTs. EL layer 3 is a light emitting layer made of an organic material. Anode 2, EL layer 3, and cathode 4 are collectively called “light emitting unit” hereafter. The light emission from the light emitting unit is controlled by TFT array unit 1.

The light emitting unit has the following structure: EL layer 3 is disposed between a pair of electrodes (anode 2 and cathode 4); a hole-transport layer is layered between anode 2 and EL layer 3; and an electron-transport layer is layered between EL layer 3 and a transparent cathode 4. TFT array unit 1 has multiple pixels 5 arranged in matrix.

Each of the pixels 5 is driven by pixel circuits 6 which are provided in each of the pixels 5. TFT array unit 1 has multiple gate wirings 7, source wirings 8, and power supply wirings 9. Gate wirings 7 are disposed in row. Source wirings 8 function as signal lines and are disposed in column so as to intersect gate wirings 7. Although it is not illustrated in FIG. 1, power supply wirings 9 extend in parallel to source wirings 8.

Each of pixel circuits 6 has TFT 10 working as a switching device, and TFT 11 working as a driving device. One gate wiring 7 connects each gate electrodes 10g, to each other in respective rows, of TFTs 10. One source wiring 8 connects each source electrodes 10s, to each other in respective columns, of TFT 10s. One power supply wiring 9 connects each drain electrodes 11d, to each other in respective columns, of TFTs 11.

As illustrated in FIG. 2, each of pixels 5 of the EL display has sub pixels 5R, 5G, and 5B in three colors (red, green, blue, sub pixels 5R, 5G, 5B are referred to simply as “sub pixels” hereafter). The sub pixels are formed on the display surface such that they are aligned in matrix. Each of the sub pixels is separated from each other by bank 5a. Bank 5a is formed by a first group of protrusions parallel to gate wirings 7 and a second group of protrusions parallel to source wirings 8. The wirings 7 and 8 cross each other. Each of the sub pixels is surrounded by bank 5a. In other words, each of the sub pixels is formed in an opening of bank 5a.

Each anode 2 is formed on an interlayer insulation film of TFT array unit 1 and in the opening of bank 5a for every sub pixel. EL layers 3 are formed separately on anodes 2 for every sub pixel. Transparent cathode 4 is formed continually so as to cover bank 5a and to cover all of the sub pixels and EL layers 3 of the EL display.

TFT array unit 1 has pixel circuits 6 provided for every sub pixels. Each of the sub pixels and its corresponding pixel circuit 6 are electrically connected by a contact hole and a relay electrode which will be described later.

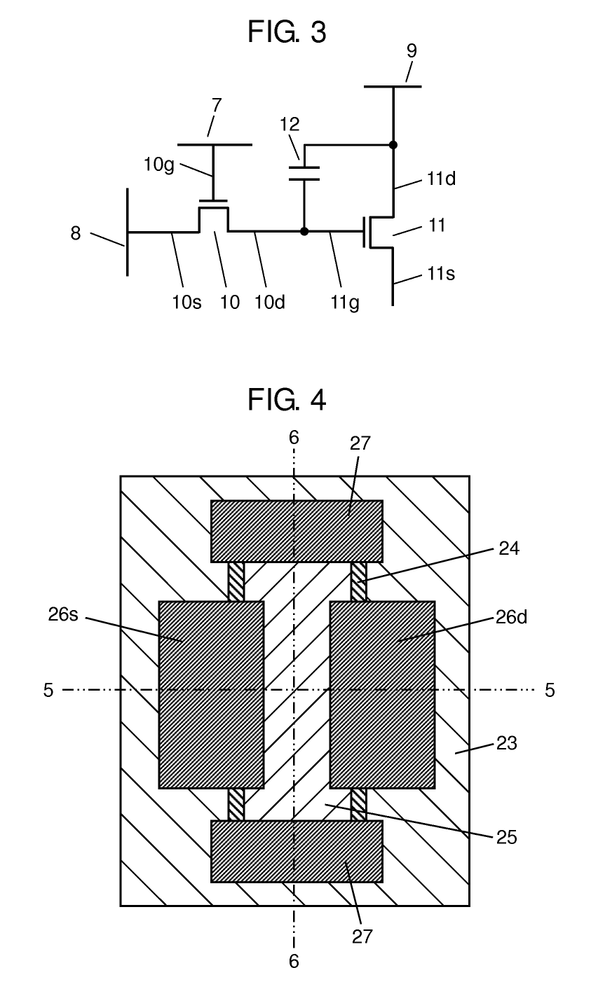

As illustrated in FIG. 3, pixel circuit 6 has TFT 10 working as a switching device, TFT 11 working as a driving device, and capacitor 12 storing data to be displayed as an image on a corresponding pixel.

TFT 10 has gate electrode 10g connected to gate wiring 7, source electrode 10s connected to source wiring 8, drain electrode 10d connected to capacitor 12 and gate electrode 11g of TFT 11, and a semiconductor film. When a voltage is applied to gate wiring 7 and source wiring 8, capacitor 12 is charged with the voltage applied to source wiring 8 as display data.

TFT 11 is configured by gate electrode 11g connected to drain electrode 10d of TFT 10, drain electrode 11d connected to power supply wiring 9 and capacitor 12, source electrode 11s connected to anode 2, and a semiconductor film.

TFT 11 supplies a current, which corresponds to the voltage value stored in capacitor 12, to anode 2 via source electrode 11s using power supply wiring 9. Thus, the EL display employs the active-matrix method that controls the display of images for every pixel 5 positioned on the intersections of gate wirings 7 and source wirings 8.

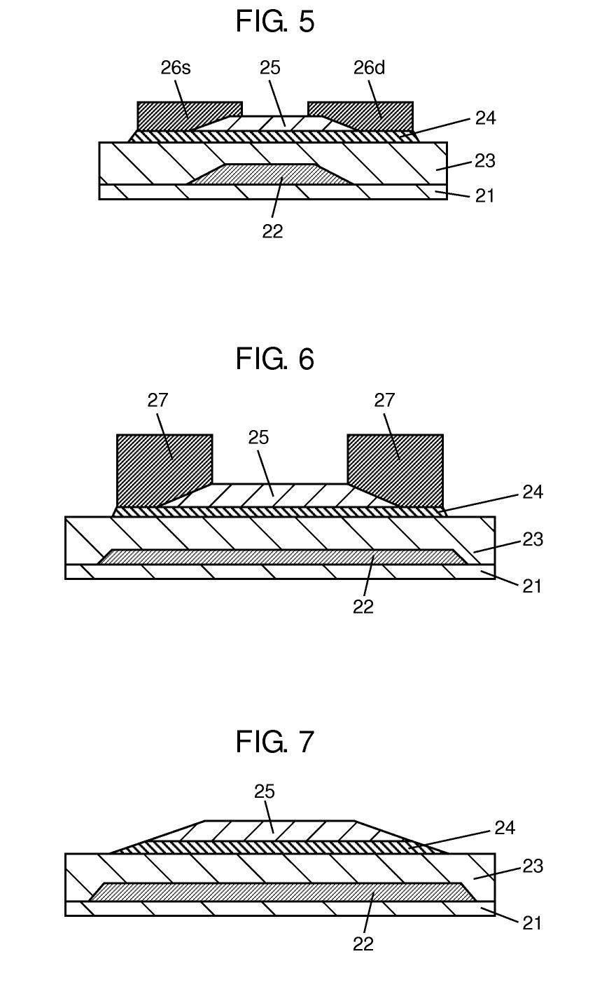

As illustrated in FIGS. 4 to 6, the TFT is configured by gate electrode 22 formed on substrate 21, a gate insulation film 23 covering gate electrode 22, an island-like oxide semiconductor layer 24 formed on gate insulation film 23, etching stopper film 25 formed on a channel forming portion of oxide semiconductor layer 24, and source electrode 26s and drain electrode 26d that are formed covering edge portions of oxide semiconductor layer 24 and etching stopper film 25.

The edge portion of etching stopper film 25, i.e. end portions in up-down direction of FIG. 4, is covered by dummy pattern 27 at a place where neither source electrode 26s nor drain electrode 26d is covering. Dummy pattern 27 is formed of material same as the electrodes 26s and 26d and is formed simultaneously with these electrodes. Dummy pattern 27 is formed such that it is electrically isolated from electrodes 26s and 26d.

The electrodes 26s and 26d have a passivation film formed thereon so as to cover these electrodes for insulating the electrodes 26d and 26s from an electrode of the light emitting layer formed in the upper layer. The electrodes 26s and 26d are connected electrically to the light emitting layer via contact holes formed in the passivation film.

Substrate 21 is made of glass substrate, for example. Alternatively, a resin substrate can be used for flexible displays. Gate electrode 22 can be made of metal, such as titanium, molybdenum, tungsten, aluminum, and gold, or of an electric conduction oxide such as ITO (Indium Tin Oxide). An alloy such as MoW can be also used as the metal. Gate electrode 22 can be also made of metal having good adhering characteristic to the oxide materials. The metal includes, e.g. a laminated material sandwiching titanium, aluminum, or gold to improve an adherence to other layers.

Gate insulation film 23 can be made either of a single layer or layered layers of an oxide thin film, e.g. silicon oxide, hafnium oxide, a nitride film, e.g. silicon nitride, or a sioxynitride film.

Oxide semiconductor layer 24 can be made of oxide semiconductor including Indium, Zinc, and Gallium, preferably in an amorphous state. Oxide semiconductor layer 24 can be formed using a DC sputtering method, an RF (Radio Frequency) sputtering method, a plasma CVD (Chemical Vapor Deposition) method, a pulsed laser deposition method, or an ink-jet printing method. Thickness of oxide semiconductor layer 24 is preferably between 10 to 150 nm. This is because a pinhole may easily generate when the thickness is smaller than 10 nm, and a leakage current during OFF operation or a subthreshold swing value (S value) of the transistor increases when the thickness is larger than 150 nm.

Etching stopper film 25 can be made of photo-sensitive organic insulating material. Source electrode 26s, drain electrode 26d, and dummy pattern 27 can be made of metal (e.g. titanium, molybdenum, tungsten, aluminum, or gold) or electric conducting oxides (e.g. ITO) similarly to gate electrode 22. An alloy such as MoW (molybdenum-tungsten) can be also used as the metal. To improve an adherence to other layers, the electrodes can be made also of layered metals sandwiching a material which adheres well to the oxide materials (e.g. titanium, aluminum, or gold).

Next, the manufacturing method of the TFT of the present disclosure is discussed.

First, form gate electrode 22 into an intended gate shape on substrate 21, and then form gate insulation film 23 so as to cover the gate electrode 22. Then form oxide semiconductor layer 24 is on gate insulation film 23. Next, form a resist mask on oxide semiconductor layer 24 and pattern the layer 24 using this resist mask. Oxide semiconductor layer 24 can be fabricated by wet etching method which uses oxalic acid, chloride or a mixture of acid, e.g. phosphoric acid, nitric acid, or acetic acid.

Next, remove the resist mask and then form etching stopper film 25. Etching stopper film 25 is made of a photosensitive material and is fabricated using a photo-lithographic method. Etching stopper film 25 is thus formed without damaging oxide semiconductor layer 24.

Next, form an electrode layer, which will become source electrode 26s, drain electrode 26d, and dummy pattern 27, and then form a resist mask. Then pattern the electrode layer using the resist mask to form source electrode 26s, drain electrode 26d, and dummy pattern 27. Formation of those elements can be done by wet etching method. After the formation of these electrodes and dummy pattern, oxide semiconductor layer 24 is then heated for 0.5 to 1200 minutes at temperature between 150 degrees to 450 degrees Celsius. This heating process reduces contact resistances between source electrode 26s and oxide semiconductor layer 24 and between drain electrode 26d and oxide semiconductor layer 24, and further stabilizes the characteristic of oxide semiconductor layer 24.

FIG. 7 is a schematic sectional view cut along line 6-6 in FIG. 4. FIG. 7 illustrates the TFT not having dummy patterns 27 on etching stopper film 25 in the end portions that are not covered with source electrodes 26s or drain electrode 26d.

As illustrated in FIG. 7, oxide semiconductor layer 24 is formed such that it overflows largely from etching stopper film 25 because the taper angle of the edge surface of etching stopper film 25 is small. This structure allows forming a parasitic transistor, and producing a hump in the I-V characteristic of the TFT.

As described above, in the present disclosure, edge portions of etching stopper film 25 are covered by dummy patterns 27 at a place where neither source electrode 26s nor drain electrode 26d is covering. Thus, oxide semiconductor layer 24 can be formed such that taper angle of end sides become larger. This prevents oxide semiconductor layer 24 from overflowing from etching stopper film 25 and can prevent the production of the hump in the I-V characteristic of TFT.

### INDUSTRIAL APPLICABILITY

The present disclosure is useful for stabilizing the characteristics of a TFT.

1. A thin film transistor comprising:
a gate electrode formed on a substrate;
a gate insulation film covering the gate electrode;
a semiconductor layer formed on the gate insulation film;
an etching stopper film formed on a channel forming portion of the semiconductor layer, and
a source electrode and a drain electrode covering an edge portion of the semiconductor layer and a first edge portion of the etching stopper film,
wherein a second edge portion, not covered with the source electrode and drain electrode, of the etching stopper film is covered with a dummy pattern.

2. The thin film transistor of claim 1, wherein the dummy pattern is made of a material same as the source electrode and the drain electrode and is electrically separated from the source electrode and the drain electrode.

3. The thin film transistor of claim 1, wherein the semiconductor layer is made of oxide semiconductor including Indium, Zinc, and Gallium.
